(19) United States
(12) Patent Application Publication
(10) Pub. No.: US 2023/0260892 A1
(43) Pub. Date: Aug. 17, 2023

(54) HYBRID BEOL DIELECTRIC FOR INCREASED DECOUPLING CAPACITANCE

(71) Applicant: INTERNATIONAL BUSINESS MACHINES CORPORATION, ARMONK, NY (US)

(72) Inventors: Ruilong Xie, Niskayuna, NY (US); Nicholas Anthony Lanzillo, Wynantskill, NY (US); Hosadurga Shobha, Niskayuna, NY (US); Lawrence A. Clevenger, Saratoga Springs, NY (US); Huai Huang, Clifton Park, NY (US)

(21) Appl. No.: 17/650,693

(22) Filed: Feb. 11, 2022

(51) Int. Cl. H01L 23/522; H01L 23/532; H01L 23/528; H01L 21/768

(52) U.S. Cl. CPC H01L 23/5223; H01L 23/53295; H01L 23/5283; H01L 21/76837; H01L 21/7682; H01L 21/76885

(57) ABSTRACT

A semiconductor structure including a metal layer including a Vdd metal line, a Vss metal line, signal lines and a high-k dielectric between the Vdd and Vss metal lines, and a dielectric surrounding the signal lines. A semiconductor structure including a metal layer including a Vdd metal line, a Vss metal line, signal lines, and a high-k dielectric between the Vdd metal line and the Vss metal line, where a width between the Vdd metal line and the Vss metal line is less than a width between each of the signal lines. A method including forming a bulk metal layer on a structure, removing portions of the bulk metal layer, remaining portions of the bulk metal layer form metal lines, the metal lines include a Vdd metal line, a Vss metal line and signal lines, and forming a high-k dielectric between the Vdd metal line and the Vss metal line.

### BACKGROUND

The present invention relates to integrated circuits, and more specifically, to interconnect layers of electrical connections.

Semiconductor wafers, chips, devices, and related devices, rely on a plurality of metallization layers or metal lines stacked on top of one another on a semiconductor substrate which provides electronic interconnections between integrated circuits on the semiconductor substrate or layer. A metallization layer may also be referred to as a back-end-of-line (BEOL) metallization layer which could be disposed on a semiconductor material stack. Semiconductor contacts in a top layer in the semiconductor material stack are electrically connected to metal contacts and metal interconnects in a metallization layer disposed on the semiconductor material stack.

The interconnect layers may be connected to devices on the integrated circuit by vias. The vias are often etched through layers of the integrated circuit and filled with a conductive material. In general, the metal lines (also referred to as wiring lines) provide electrical connections within the same metal level, and the conductive vias provide inter-level or vertical connections between different (metal) line levels.

### SUMMARY

According to an embodiment of the present invention, a semiconductor structure is provided. The semiconductor structure including a metal layer including a Vdd metal line, a Vss metal line, one or more signal lines and a high-k dielectric between the Vdd metal line and the Vss metal line, and a dielectric surrounding the one or more signal lines, the dielectric including a dielectric constant less than or equal to 3.9.

According to an embodiment of the present invention, a semiconductor structure is provided. The semiconductor structure including a metal layer including a Vdd metal line, a Vss metal line, and one or more signal lines, and a high-k dielectric between the Vdd metal line and the Vss metal line, where a width between the Vdd metal line and the Vss metal line is less than a width between each of the one or more signal lines.

According to an embodiment of the present invention, a method is provided. The method including forming a bulk metal layer on a structure, removing portions of the bulk metal layer, where remaining portions of the bulk metal layer form metal lines, where the metal lines include a Vdd metal line, a Vss metal line and one or more signal lines, and forming a high-k dielectric between the Vdd metal line and the Vss metal line.

Additional features and advantages are realized through the techniques of the present invention. Other embodiments and aspects of the invention are described in detail herein and are considered a part of the claimed invention. For a better understanding of the invention with the advantages and the features, refer to the description and to the drawings.

### BRIEF DESCRIPTION OF THE DRAWINGS

These and other objects, features and advantages of the present invention will become apparent from the following detailed description of illustrative embodiments thereof, which is to be read in connection with the accompanying drawings. The various features of the drawings are not to scale as the illustrations are for clarity in facilitating one skilled in the art in understanding the invention in conjunction with the detailed description. In the drawings:

FIG. 1 illustrates a cross sectional side view, of a semiconductor structure at an intermediate stage of fabrication, according to an exemplary embodiment;

FIG. 2 is a cross sectional side view of the semiconductor structure and illustrates formation of a metal layer and a via layer, according to an exemplary embodiment;

FIG. 3 is a cross sectional side view of the semiconductor structure and illustrates formation of a metal line and formation of a second metal layer, according to an exemplary embodiment;

FIG. 4 is a cross sectional side view of the semiconductor structure and illustrates formation of a hard mask and patterning the second metal layer, according to an exemplary embodiment;

FIG. 5 is a cross sectional side view of the semiconductor structure and illustrates formation of a high-k dielectric, according to an exemplary embodiment;

FIG. 6 is a cross sectional side view of the semiconductor structure and illustrates an isotropic etch, according to an exemplary embodiment;

FIG. 7 is a cross sectional side view of the semiconductor structure and illustrates formation of a low-k dielectric, according to an exemplary embodiment; and

FIG. 8 is a cross sectional side view of the semiconductor structure and illustrates an alternate embodiment, according to an exemplary embodiment.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. In the description, details of well-known features and techniques may be omitted to avoid unnecessarily obscuring the presented embodiments.

Embodiments of the present invention relate to integrated circuits, and more specifically, to interconnect layers of electrical connections. The following described exemplary embodiments provide a system, method, and program product to, among other things, provide subtractive metallization by removing select portions of metal lines after metallization, putting power and ground lines next to one another, which increases decoupling capacitance which decreases power supply noise. Additionally, a high-k dielectric between the power and ground lines further increases decoupling capacitance between the power and ground lines.

The present embodiment has the capacity to improve the technical field of integrated circuits by providing a footprint reduction, and decreased power supply noise.

As previously described, semiconductor wafers, chips, devices, and related devices, rely on a plurality of metallization layers or metal lines stacked on top of one another on a semiconductor substrate which provides electronic interconnections between integrated circuits on the semiconductor substrate or layer. A metallization layer may also be referred to as a back-end-of-line (BEOL) metallization layer which could be disposed on a semiconductor material stack. Semiconductor contacts in a top layer in the semiconductor material stack are electrically connected to metal contacts and metal interconnects in a metallization layer disposed on the semiconductor material stack. The interconnects may be connected vertically to other interconnects or to devices on the integrated circuit using vias. The conductive lines are often formed from metallic materials such as, for example, copper, silver, aluminum, tungsten, molybdenum, ruthenium, or an alloy such as copper tungsten. Prior to depositing the metallic material, a liner layer may be deposited in a channel that defines the line. A cap liner may also be deposited over the metallic material following the formation of the line. The cap liner layer is often used to reduce metal migration into the dielectric or discourage oxidation on the metallic material.

Traditional patterning techniques such as lithography etch (LE), self-aligned double patterning (SADP), self-aligned litho-etch-litho-etch (SALELE), self aligned block (SAB) for BEOL metallization such as copper single-damascene or dual-damascene and novel subtractive metallization are dependent upon block lithographic patterning to separate lines and vias, in order to enable minimal distance between lines, both tip to tip (T2T) and tip to side (T2S), and via edge to edge (E2E). Using traditional patterning techniques, overall distances between elements cannot be reduced beyond lithographic patterning limits without jeopardizing the final product performance due to the mask design and patterning process.

Subtractive metallization is a process to remove portions of a metal layer after deposition to form some part of the BEOL interconnect. Subtractive metallization is different than single damascene (SD) and dual damascene (DD), which utilizes a process where metallization is deposited in a pre-formed interconnected patterning.

As such, it may be advantageous to strategically remove portions of metallized lines and vias to improve areas such that the T2T, T2S and via E2E can each be reduced to smaller dimensions and spacing and have an improved isolation by addition of a better dielectric film formed in areas of isolation between metal lines and vias.

The BEOL may include several layers of metal lines, each with a via layer between a pair of adjacent layers of metal lines. Each layer of metal lines may include a low-k dielectric surrounding and isolating metal lines. Each layer of metal lines may include one or more power lines, one or more ground lines, and multiple signal lines. Traditionally, each power line may be physically separated from each ground line, with signal lines between them. In some embodiments, each power line may run adjacent to a ground line. These embodiments include standard minimum spacing between power lines, ground lines and signal lines.

In an embodiment of this invention, a power line may run adjacent to a ground line, and a high-k dielectric may separate the power line and the ground line. A low-k dielectric may separate all other metal lines. In a preferred embodiment of this invention, a minimum spacing between an adjacent power line and ground line may be less than a minimum spacing between all other metal lines.

Advantages of using a high-k dielectric between an adjacent power line and ground line include an increase of decoupling capacitance between the adjacent power line and ground line. An additional advantage is allowance of tighter spacing between the adjacent power line and ground line. Additionally, a structure with a high-k dielectric between an adjacent power line and ground line with tighter spacing between them may allow a reduction in cell height for the layer of metal lines, resulting in a scaling reduction and size reduction of the structure. In an embodiment, this invention may result in approximately a 5% reduction in cell height, translating directly to a 5% area scaling reduction.

An advantage of having the power line and ground line adjacent to each other is that there are larger open spaces which provide more flexibility when signal routing the other lines of the metal layer.

Advantages of an increased decoupling capacitance between the adjacent power line and ground line include a reduction in power supply noise, better current control, especially in high performance computing (HPC) chips.

In an embodiment, there may be up to 18 layers of metal lines, with a via layer between each layer of metal lines. Embodiments of this invention may be used for one or more of the several layers of metal lines, including all 18 layers of metal lines. Each of the layers of metal lines may include power lines, ground lines and signal lines.

The following described exemplary embodiments provide a method and structure to use a high-k dielectric between an adjacent power line and ground line, with closer spacing between the adjacent power line and ground line than spacing between other metal lines in a BEOL metal layer.

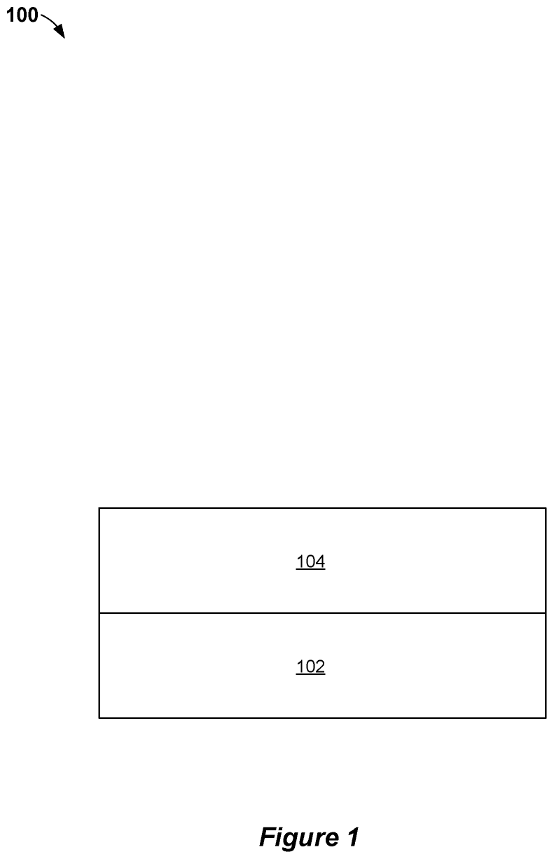

Referring now to FIG. 1, a cross sectional side view of a semiconductor structure 100 (hereinafter “structure”) at an intermediate stage of fabrication is shown according to an exemplary embodiment.

The structure 100 may include a substrate 102 and layers 104. The substrate 102 may be a bulk substrate, which may be made from any of several known semiconductor materials such as, for example, silicon, germanium, silicon-germanium alloy carbon-doped silicon-germanium alloy, and compound (e.g. III-V and II-VI) semiconductor materials. Non-limiting examples of compound semiconductor materials include gallium arsenide, indium arsenide, and indium phosphide. In other embodiments, the substrate 102 may be, for example, a layered semiconductor such as Si/SiGe, a silicon-on-insulator, or a SiGe-on-insulator, where a buried insulator layer separates a base substrate from a top semiconductor layer. In such cases, components of the structure 100 may be formed in or from the top semiconductor layer of the SOI substrate. Typically the substrate 102 may be approximately, but is not limited to, several hundred microns thick.

The layers 104 may include both front end of line (FEOL) layers and middle of line (MOL) layers. The FEOL layers may include multiple layers of individual devices, such as transistors, capacitors, resistors, etc. The MOL layers may include contact structures connecting the FEOL layers and back end of line (“BEOL”) layers, not yet formed. In general, the back end of line (BEOL) is the second portion of integrated circuit fabrication where the individual devices (transistors, capacitors, resistors, etc.) are interconnected with wiring on the wafer.

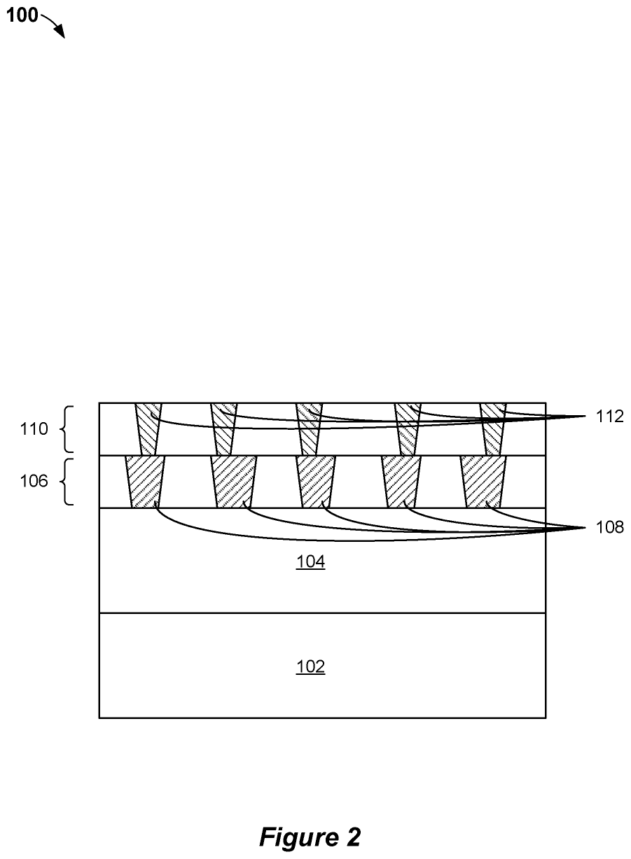

Referring now to FIG. 2, the structure 100 is shown according to an exemplary embodiment. A first metal layer and a first via layer are formed.

The first metal layer may include a dielectric 106 and metal lines 108. The first via layer may include a dielectric 110 and vias 112. The first metal layer and the first via layer may be formed by traditional methods known in the art.

The dielectric 106 may be formed by conformally depositing or growing a dielectric on the structure 100. The dielectric 106 may be formed by deposition via a process that grows, coats, or otherwise transfers a material onto the structure 100. The dielectric 106 may be deposited by physical vapor deposition (PVD), chemical vapor deposition (CVD), electrochemical deposition (ECD), molecular beam epitaxy (MBE), and atomic layer deposition (ALD), among others. The dielectric 106 may include one or more layers. The dielectric 106 may be composed of, for example, silicon oxide (SiOx), silicon nitride (SiNx), silicon boron carbonitride (SiBCN), NBLoK, a low-k dielectric material (with k<4.0), including but not limited to, silicon oxide, spin-on-glass, a flowable oxide, a high density plasma oxide, borophosphosilicate glass (BPSG), or any combination thereof or any other suitable dielectric material.

Trenches (not shown) may be formed in the dielectric 106, by, for example, reactive ion etching (RIE), for subsequent filling to form the metal lines 108. The metal lines 108 can include, for example, a conductive etchable metal such as, aluminum (Al), tungsten (W), ruthenium (Ru), molybdenum (Mo) tantalum (Ta), titanium (Ti), silver (Ag), phase-change memory (PCM) materials such as germanium-antimony-tellurium (GST), MRAM metal stack or a combination of materials. The metal lines 108 can be formed by for example, physical vapor deposition (PVD), an electroplate fill process, or other method. The metal lines 108 are embedded in the dielectric 106. There may be any number of metal lines 108.

A chemical mechanical polishing (CMP) technique may be used to remove excess material and polish upper surfaces of the structure 100, providing a uniform horizontal surface.

The dielectric 110 may be formed on the structure as described for the dielectric 106. Openings (not shown) may be formed in the dielectric 110, for example, by reactive ion etching (RIE), for subsequent filling to form the vias 112. The vias 112 can include, for example, a conductive etchable metal such as, aluminum (Al), tungsten (W), ruthenium (Ru), molybdenum (Mo) tantalum (Ta), titanium (Ti), silver (Ag), phase-change memory (PCM) materials such as germanium-antimony-tellurium (GST), MRAM metal stack or a combination of materials. The vias 112 can be formed by for example, physical vapor deposition (PVD), an electroplate fill process, or other method. The vias 112 are embedded in the dielectric 110. There may be any number of vias 112. Each of the vias 112 may me physically and electrically connected to a point on one of the metal lines 108 for subsequent physical and electrical connection of further lines and vias formed on the structure 100.

A chemical mechanical polishing (CMP) technique may be used to remove excess material and polish upper surfaces of the structure 100, providing a uniform horizontal surface.

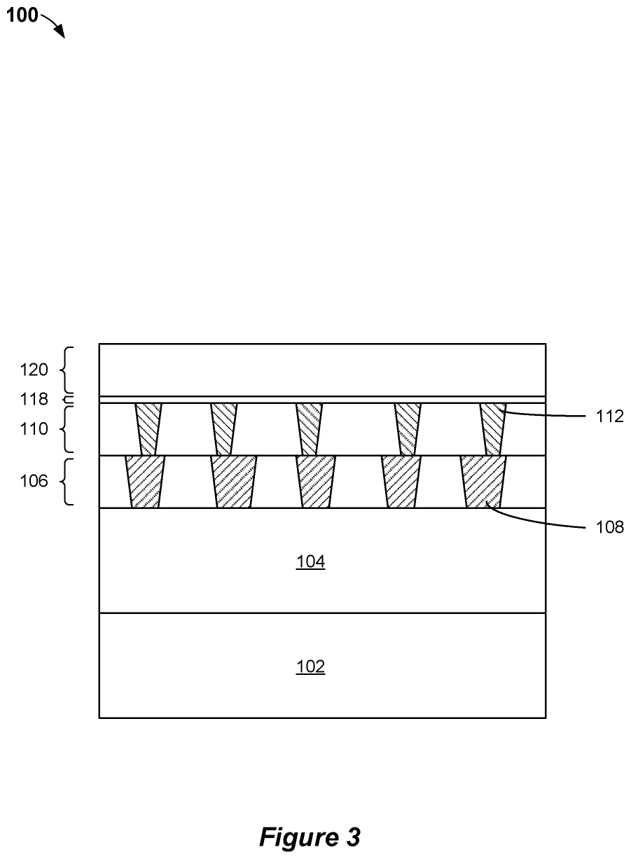

Referring now to FIG. 3, the structure 100 is shown according to an exemplary embodiment. A metal liner 118 and a bulk metal 120 are formed.

The metal liner 118 may be conformally formed on the structure 100. The metal liner 118 may cover an upper horizontal surface of the vias 112 and the dielectric 110 of the first via layer. The metal liner 118 can include, for example, titanium nitride (TiN), tantalum nitride (TaN), titanium (Ti), tantalum (Ta), tungsten (W), tungsten nitride (N₂W₃), or other suitable materials. The metal liner 118 can be formed by for example, atomic layer deposition (ALD), chemical vapor deposition (CVD), plasma-assisted CVD, sputtering, plating and chemical solution deposition, among others.

The metal liner 118 acts as a barrier to prevent metallic migration into the dielectric 110, or into other components of the structure 100, and also as an adhesion to the bulk metal 120 and to reduce or discourage oxidation on the metallic material.

The bulk metal 120 may be formed conformally on the structure 100, on the metal liner 118. The bulk metal 120 can include, for example, a conductive etchable metal such as, ruthenium (Ru), aluminum (Al), tungsten (W), molybdenum (Mo) tantalum (Ta), titanium (Ti), silver (Ag), cobalt (Co), platinum (Pt), alloys of conductive metal compounds like tantalum nitride (TaN), titanium nitride (TiN), tantalum carbide TaCx, titanium carbide (TiC), tungsten carbide (WC), tungsten silicide (WSi₂), or other suitable materials. The bulk metal 120 can be formed by for example, physical vapor deposition (PVD), chemical vapor deposition, (CVD) plasma enhanced CVD, sputtering, plating, chemical solution deposition, electroless plating, an electroplate fill process, or other method.

In an embodiment, a metal liner 118 is not used, and the bulk metal 120 is formed directly on the upper horizontal surface of the vias 112 and the dielectric 110 of the first via layer. In this embodiment, the bulk metal 120 may include ruthenium (Ru), which is a noble metal which may not diffuse into the dielectric 110, and neither a barrier metal nor a metal liner is required between the dielectric 110 and the build metal 120.

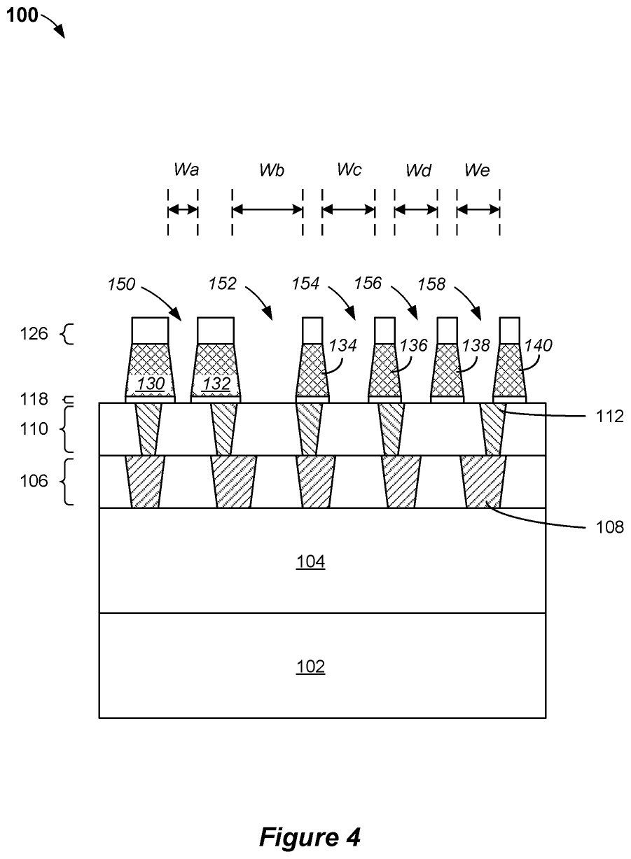

Referring now to FIG. 4, the structure 100 is shown according to an exemplary embodiment. A hard mask 126 may be formed, and the hard mask 126, the bulk metal 120 and the metal liner 118 may be patterned, forming a second metal layer.

The hard mask 126 may include a photoresist layer patterned by known techniques using optical or EUV lithographic patterning to remove portions of the hard mask 126, the bulk metal 120 and the metal liner 118, resulting in spaces 150, 152, 154, 156 and 158. Portions of an upper surface of the dielectric 110 may be exposed where the hard mask 126, the bulk metal 120 and the metal liner 118 were removed.

The patterning which removes the hard mask 126, the bulk metal 120 and the metal liner 118 results in remaining portions of the bulk metal 120 which form metal lines 130, 132, 134, 136, 138 and 140, each of which are covered by the hard mask 126.

In an embodiment, the metal line 130 may be supply voltage or power, Vdd, and the metal line 132 may be ground, Vss. In an embodiment, the metal lines 130, 132, or Vdd, Vss, may be adjacent to each other.

A width between the metal lines 130, 132, or Vdd, Vss, may be Wa. A width between the metal lines 132, 134 may be Wb. A width between the metal lines 134, 136 may be Wc. A width between the metal lines 136, 138 may be Wd. A width between the metal lines 138, 140 may be We.

The width between the metal lines 130, 132, or Vdd, Vss, Wa, may be patterned as a smaller width than the spacing between the other word lines, including Wb, Wc, Wd, and We.

The forming of the bulk metal 120 and patterning to remove portions of the bulk metal 120 to form word lines 130, 132, 134, 136, 138, 140, may be referred to as substrative metal patterning.

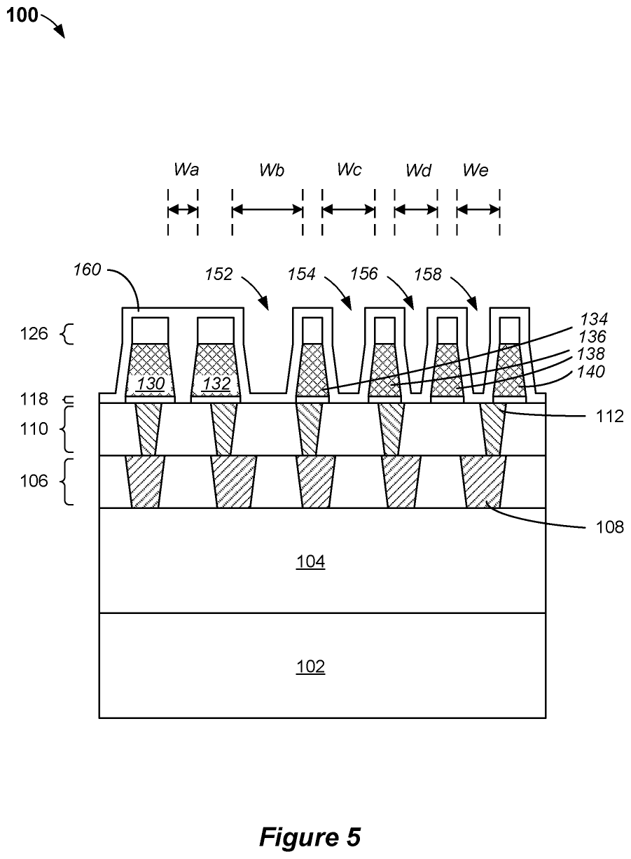

Referring now to FIG. 5, the structure 100 is shown according to an exemplary embodiment. A high-k dielectric 160 may be formed conformally on the structure 100.

The high-k dielectric 160 may be conformally formed on the structure 100, covering exposed upper surfaces of the dielectric 110, side surfaces of the metal liner 118, side surfaces of the metal lines 130, 132, 134, 136, 138, 140, and a side surface and an upper surface of the hard mask 126. The high-k dielectric 160 may be deposited using typical deposition techniques, for example, atomic layer deposition (ALD), molecular layer deposition (MLD), chemical vapor deposition (CVD), physical vapor deposition (PVD), high density plasma (HDP) deposition, and spin on techniques, followed by an anisotropic vertical etch process such as a reactive ion etch (RIE), or any suitable etch process. In an embodiment, the high-k dielectric 160 may include one or more layers. The high-k dielectric 160 may include materials such as AlOₓ, SiN, AlNₓ, HfO2, ZrO2, Al₂O₃, La₂O₃, TiO₂, SrTiO₃, LaAlO₃, Y₂O₃, HfOxNy, silicate thereof, and an alloy thereof. A thickness of the high-k dielectric 160 may in a the range of 2-20 nm.

The high-k dielectric 160 may completely fill the space 150 between the metal liner 118, the metal lines 130, 132, or Vdd, Vss, and the hard mask 126 over the metal lines 130, 132. The high-k dielectric 160 may form a liner along spaces 152, 154, 156, 158, between the word lines 132, 134, 136, 138, 140, leaving the spaces 152, 154, 158, 160. This is due to the spacing, Wa, being less than the spacing Wb, Wc, Wd, We. The forming of the high-k dielectric 160 may be controlled to fill the space 150 while not filling the spaces 152, 154, 156, 158, based on a material and process used, and lengths of the spaces Wa, Wb, Wc, Wd, We.

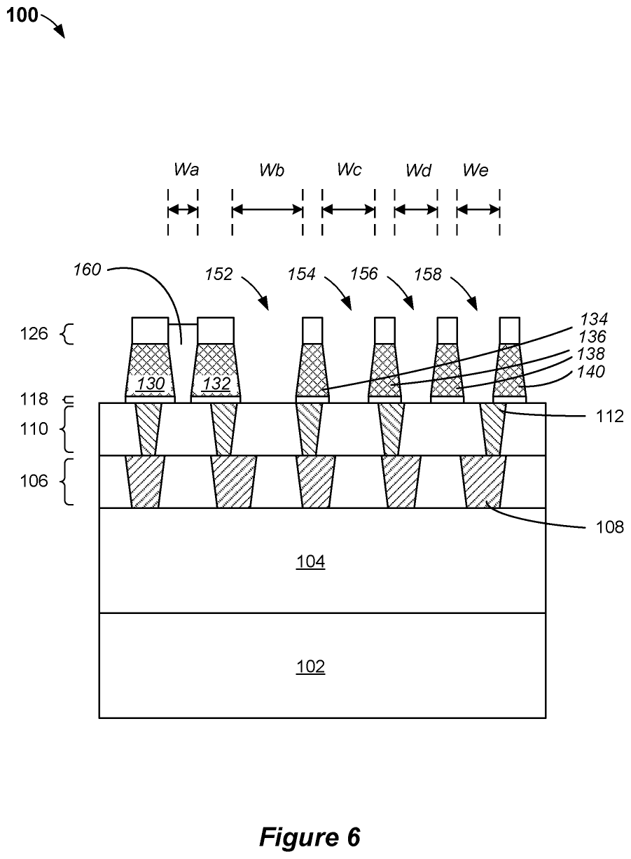

Referring now to FIG. 6, the structure 100 is shown according to an exemplary embodiment. An isotropic etch may remove a portion of the high-k dielectric 160.

An anisotropic vertical etch process such as a reactive ion etch (RIE), or any suitable etch process may remove the high-k dielectric 160 from the upper surfaces of the metal lines 130, 132, 134, 136, 138, 140. The high-k dielectric 160 may be removed from vertical side surfaces of the metal lines 134, 136, 138, 140. The high-k dielectric 160 may be removed from upper surface of the dielectric 110 between the metal lines 132, 134, between the metal lines 134, 136, between the metal lines 136, 138, and between the metal lines 138, 140.

The high-k dielectric 160 may be remain between the metal lines 130, 132, or Vdd, Vss. An upper surface of the remaining high-k dielectric 160 may be below an upper surface of the hard mask 126 above the metal lines 130, 132. The upper surface of the high-k dielectric 160 may be above an upper surface of the metal lines 130, 132, as measured from an upper surface of the substrate 102. The high-k dielectric 160 may be remain between the metal lines 130, 132, or Vdd, Vss due to the spacing, Wa, being less than the spacings Wb, Wc, Wd, We. The high-k dielectric 160 may be removed from a first side of the metal line 130 and remain on a second side of the metal line 130, remaining between the metal lines 130, 132. The high-k dielectric 160 may remain on a first side of the metal line 132 and be removed from a second side of the metal line 132.

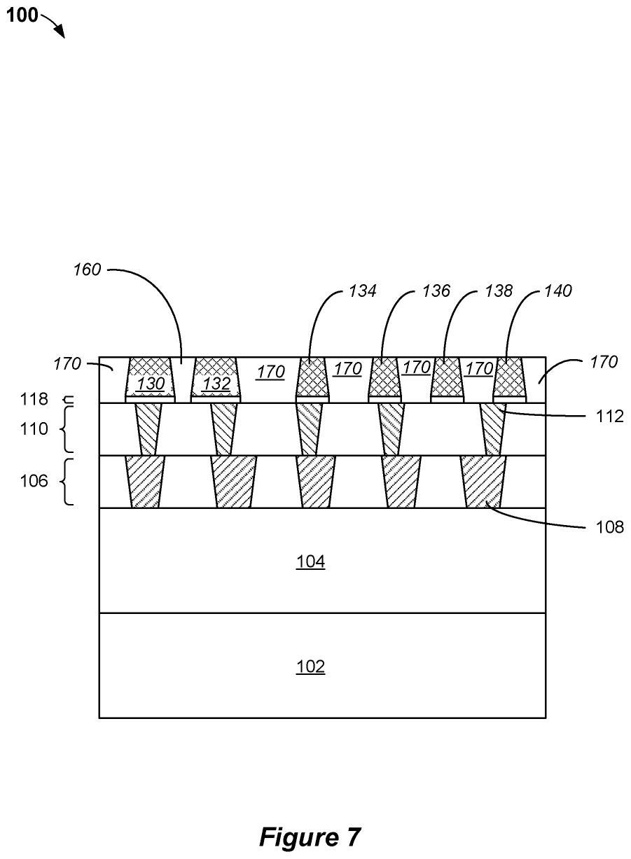

Referring now to FIG. 7, the structure 100 is shown according to an exemplary embodiment. A low-k dielectric 170 may be formed on the structure 100.

The low-k dielectric 170 may be formed as described for the dielectric 106. The low-k dielectric 170 may fill the spaces 152, 154, 156, 158 and cover the exposed upper surface of the dielectric 110. The low-k dielectric 170 may cover side surfaces of the metal liner 118 and side surfaces of the metal lines 134, 136, 138, 140. The low-k dielectric 170 may cover the first side surface of the metal line 130 and may cover the second side surface of the metal line 132.

A CMP technique may be used to remove excess material and polish upper surfaces of the structure 100 and remove the hard mask 126, providing a uniform horizontal surface of the low-k dielectric 170, the high-k dielectric 160 and the word lines 130, 132, 134, 136, 138, 140, thus forming the second metal layer.

The second metal layer is formed by subtractive metal patterning and is an alternative method to form a metal layer than as described above for the first metal layer. Each of the metal layers of the structure 100 may be formed as described for the first metal layer or as described for the second metal layer. There may be a via layer between each layer of the structure 100, as described for the first via layer. In an embodiment, there may be 18 metal layers in the structure 100. In an embodiment, all the metal layers may be formed by subtractive metal patterning. In an embodiment, a subset of the metal layers may be formed by substrative metal patterning.

The second metal layer has metal lines 130, 132, or Vdd, Vss, with the high-k dielectric 160 between the metal lines 130, 132, and has the low-k dielectric 170 surrounding all other metal lines 134, 136, 138, 140. The high-k dielectric 160 between Vdd, Vss provides a decoupling capacitance which decreases power supply noise on the structure 100.

In an embodiment, the high-k dielectric 160 includes a dielectric constant equal to or greater than 5.0. The dielectric 106, the dielectric 110 and the low-k dielectric 170 may have a dielectric constant equal to or below 3.9.

In an embodiment, a profile of the metal lines 130, 132, 134, 136, 138, 140 is negatively tapered, where critical dimension at a bottom of the metal lines 130, 132, 134, 136, 138, 140 is greater than a critical dimension at a top of the metal lines 130, 132, 134, 136, 138, 140 (further from the substrate 102).

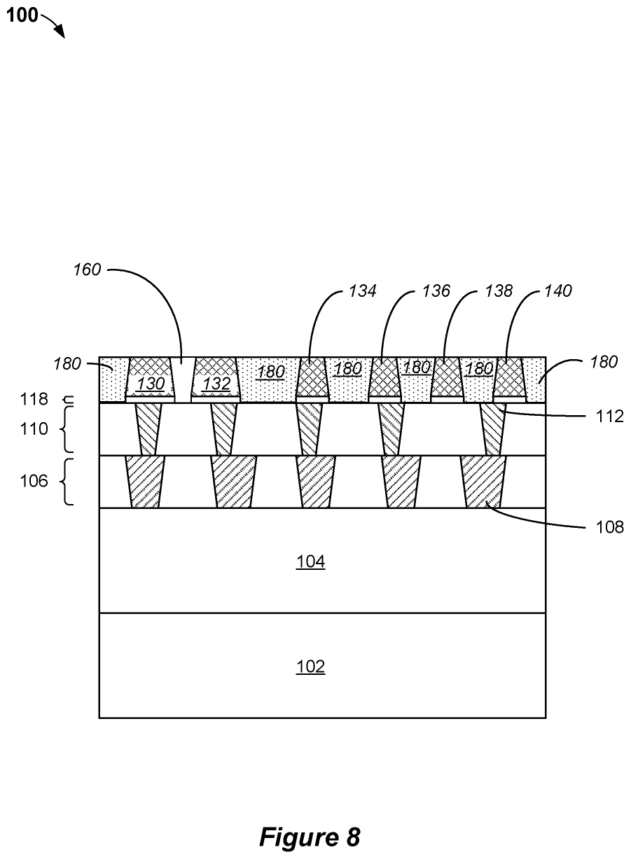

Referring now to FIG. 8, the structure 100 is shown according to an alternate embodiment than FIG. 7. Following the steps described in FIG. 6, a low-k dielectric with air-gap 180 may be formed on the structure 100, rather than forming the low-k dielectric 170.

The low-k dielectric with air-gap 180 may be formed as described for the dielectric 106 and may be formed with process constraints which allow the material to be formed with air-gaps within the material.

The low-k dielectric with air-gap 180 may fill the spaces 152, 154, 156, 158 and cover the exposed upper surface of the dielectric 110. The low-k dielectric with air-gap 180 may cover side surfaces of the metal liner 118 and side surfaces of the metal lines 134, 136, 138, 140. The low-k dielectric with air-gap 180 may cover the first side surface of the metal line 130 and may cover the second side surface of the metal line 132.

A CMP technique may be used to remove excess material and polish upper surfaces of the structure 100 and remove the hard mask 126, providing a uniform horizontal surface of the low-k dielectric with air-gap 180, the high-k dielectric 160 and the word lines 130, 132, 134, 136, 138, 140, thus forming an alternate second metal layer.

The alternative second metal layer is formed by subtractive metal patterning and is an alternative method to form a metal layer than as described above for the first metal layer and may be used for one or more of the metal layers for the structure 100.

The low-k dielectric with air-gap 180 may have an advantage of increased thermal and electrical isolation between metal lines 132, 134, 136, 138, 140, compared to the low-k dielectric 170.

In an embodiment, the high-k dielectric 160 does not have air-gaps.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one more other features, integers, steps, operations, element components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

The diagrams depicted herein are just one example. There may be many variations to this diagram or the steps (or operations) described therein without departing from the spirit of the invention. For instance, the steps may be performed in a differing order or steps may be added, deleted or modified. All of these variations are considered a part of the claimed invention.

While the preferred embodiment to the invention had been described, it will be understood that those skilled in the art, both now and in the future, may make various improvements and enhancements which fall within the scope of the claims which follow. These claims should be construed to maintain the proper protection for the invention first described.

What is claimed is:

1. A semiconductor structure comprising:
a metal layer comprising a Vdd metal line, a Vss metal line, and one or more signal lines;
a high-k dielectric between the Vdd metal line and the Vss metal line; and
a dielectric surrounding the one or more signal lines, the dielectric comprising a dielectric constant less than or equal to 3.9.

2. The semiconductor structure according to claim 1, wherein
a width between the Vdd metal line and the Vss metal line is less than a width between each of the one or more signal lines.

3. The semiconductor structure according to claim 1, wherein
the high-k dielectric comprises a dielectric constant greater than or equal to 5.0.

4. The semiconductor structure according to claim 1, wherein
the dielectric between the Vdd metal line and the one or more signal lines, the dielectric between the Vss metal line and the one or more signal lines.

5. The semiconductor structure according to claim 1, wherein
a metal profile of the Vdd metal line, the Vss metal line and the one or more signal lines is negatively tapered.

6. The semiconductor structure according to claim 1, wherein
a dielectric surrounding the one or more signal lines comprises air-gaps.

7. The semiconductor structure according to claim 1, wherein
a width between the one or more signal lines and the Vdd metal line is greater than a width between the Vdd metal line and the Vss metal line.

8. A semiconductor structure comprising:
a metal layer comprising a Vdd metal line, a Vss metal line, and one or more signal lines; and
a high-k dielectric between the Vdd metal line and the Vss metal line, wherein
a width between the Vdd metal line and the Vss metal line is less than a width between each of the one or more signal lines.

9. The semiconductor structure according to claim 8, wherein
the high-k dielectric comprises a dielectric constant greater than or equal to 5.0.

10. The semiconductor structure according to claim 8, wherein
a dielectric surrounding the one or more signal lines comprises a dielectric constant less than or equal to 3.9.

11. The semiconductor structure according to claim 8, wherein
a metal profile of the Vdd metal line, the Vss metal line and the one or more signal lines is negatively tapered.

12. The semiconductor structure according to claim 8, wherein
a dielectric surrounding the one or more signal lines comprises air-gaps.

13. The semiconductor structure according to claim 8, wherein
a width between the one or more signal lines and the Vdd metal line is greater than a width between the Vdd metal line and the Vss metal line.

14. A method of forming a structure, the method comprising:
forming a bulk metal layer on the structure;
removing portions of the bulk metal layer, wherein remaining portions of the bulk metal layer form metal lines,
wherein the metal lines comprise a Vdd metal line, a Vss metal line and one or more signal lines; and
forming a high-k dielectric between the Vdd metal line and the Vss metal line.

15. The method according to claim 14, wherein
a width between the Vdd metal line and the Vss metal line is less than a width between each of the one or more signal lines.

16. The method according to claim 14, wherein
the high-k dielectric comprises a dielectric constant greater than or equal to 5.0.

17. The method according to claim 14, wherein
a dielectric surrounding the one or more signal lines comprises a dielectric constant less than or equal to 3.9.

18. The method according to claim 14, wherein
a metal profile of the Vdd metal line, the Vss metal line and the one or more signal lines is negatively tapered.

19. The method according to claim 14, wherein
a dielectric surrounding the one or more signal lines comprises air-gaps.

20. The method according to claim 14, wherein
a width between the one or more signal lines and the Vdd metal line is greater than a width between the Vdd metal line and the Vss metal line.
